(19) United States
(12) Patent Application Publication
(10) Pub. No.: US 2026/0354002 A1
(43) Pub. Date: Nov. 5, 2026

(54) TRANSPARENT DISPLAY APPARATUS

(71) Applicant: LG Display Co., Ltd., Seoul (KR)

(72) Inventors: Binn KIM, Paju-si (KR); DongYoon KIM, Paju-si (KR)

(73) Assignee: LG Display Co., Ltd., Seoul (KR)

(21) Appl. No.: 19/662,706

(22) Filed: Apr. 29, 2026

(30) Foreign Application Priority Data
Apr. 30, 2025 (KR) 10-2025-0057526

(51) Int. Cl. H10K 59/88; H10H 29/37; H10H 29/45; H10H 29/85; H10K 59/122; H10K 59/127; H10K 59/35; H10K 59/38; H10K 102/00

(52) U.S. Cl. CPC H10K 59/88; H10H 29/37; H10H 29/45; H10H 29/8517; H10K 59/122; H10K 59/127; H10K 59/351; H10K 59/38; H10K 2102/351

(57) ABSTRACT

A transparent display apparatus can include a display area in which a plurality of pixels each having a first non-transmissive area and a first transmissive area are disposed, a bezel area adjacent to the display area and in which a plurality of dummy pixels each having a second non-transmissive area and a second transmissive area are disposed, a first dummy color pattern partially disposed in the first transmissive area, and a second dummy color pattern partially disposed in the second transmissive area. An area of the second dummy color pattern can vary depending on a position in the bezel area.

### CROSS-REFERENCE TO RELATED APPLICATION

This application claims priority to Korean Patent Application No. 10-2025-0057526, filed in the Republic of Korea on Apr. 30, 2025, which is hereby expressly incorporated by reference in its entirety.

### BACKGROUND

### Field of Technology

The present disclosure relates to a transparent display apparatus capable of reducing or minimizing a color difference between a display area and a bezel area.

### Discussion of the Related Art

A transparent display apparatus can include a non-transmissive area (light emitting area) and a transmissive area, and can display a full-color image using subpixels disposed in the non-transmissive area.

In the transparent display apparatus, a light emitting layer of a light emitting element can be commonly disposed in the non-transmissive area and the transmissive area. A color change can occur in the transmissive area due to an organic material such as the light emitting layer.

In the transparent display apparatus, a color difference can occur between the display area and the bezel area depending on the presence or absence of the light emitting layer.

In the transparent display apparatus, a color difference can occur between a first area of the bezel area in which the light emitting layer extending from the display area is disposed and a second area of the bezel area in which no light emitting layer is present.

In the transparent display apparatus, a color difference can occur in the first area of the bezel area in which the light emitting layer is disposed, depending on the thickness of the light emitting layer.

### SUMMARY OF THE DISCLOSURE

The present disclosure provides a transparent display apparatus capable of reducing or minimizing a color difference between a display area and a bezel area depending on the presence or absence of a light emitting layer.

The present disclosure provides a transparent display apparatus capable of reducing or minimizing a color difference in a bezel area depending on the presence or absence of a light emitting layer and the thickness of the light emitting layer.

The technical problems to be solved by the present disclosure are not limited to the above-mentioned problems, and other problems not mentioned herein will be clearly understood by those skilled in the art from the following description.

According to at least one embodiment of the present disclosure, a transparent display apparatus can include a display area in which a plurality of pixels each having a first non-transmissive area and a first transmissive area are disposed, a bezel area adjacent to the display area in which a plurality of dummy pixels each having a second non-transmissive area and a second transmissive area are disposed, a first dummy color pattern partially disposed in the first transmissive area, and a second dummy color pattern partially disposed in the second transmissive area, and an area of the second dummy color pattern can vary depending on a position in the bezel area. The area of the second dummy color pattern can vary according to a thickness of a light emitting layer disposed in the plurality of dummy pixels.

According to at least one embodiment of the present disclosure, a transparent display apparatus can include a display area in which pixels each having a transmissive area and a non-transmissive area are disposed, a bezel area adjacent to the display area in which dummy pixels each having a transmissive area and a non-transmissive area are disposed, and a dummy color pattern partially disposed in the transmissive area of the pixel and the transmissive area of the dummy pixel, and an area of the dummy color pattern of the dummy pixel in the bezel area can vary depending on a distance from the display area. The area of the dummy color pattern of the dummy pixel in the bezel area can vary in proportion to a thickness of a light emitting element layer disposed in the dummy pixel.

According to at least one embodiment of the present disclosure, a transparent display apparatus can include a display area in which pixels each having a transmissive area and a non-transmissive area are disposed, a bezel area adjacent to the display area in which dummy pixels each having a transmissive area and a non-transmissive area are disposed, and a color compensation pattern partially disposed in the transmissive area of the pixel and the transmissive area of the dummy pixel, and an area of the color compensation pattern of the dummy pixel in the bezel area can vary in proportion to a thickness of a light emitting element layer disposed in the dummy pixel.

The specific matters according to various examples of the present disclosure other than the means for solving the above-mentioned problems are included in the following description and drawings.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure.

In the drawings:

FIG. 1 is a block diagram schematically illustrating a configuration of a transparent display apparatus according to an embodiment of the present disclosure.

FIGS. 2A and 2B are views schematically illustrating a pixel configuration of a transparent display apparatus according to an embodiment of the present disclosure.

FIG. 3 is an equivalent circuit diagram illustrating a configuration of a subpixel according to an embodiment of the present disclosure.

FIG. 4 is a view illustrating a color-difference phenomenon of a transparent display apparatus according to a comparative example of the present disclosure.

FIG. 5 is a view schematically illustrating a display panel according to an embodiment of the present disclosure.

FIG. 6 is an enlarged view of portion RA in the transparent display panel according to the embodiment shown in FIG. 5.

FIG. 7 is a graph illustrating a relationship between an area of a dummy color pattern and a color difference in a transparent display apparatus according to an embodiment of the present disclosure.

FIG. 8 is a graph illustrating transmittances of R/G/B light in a transmissive portion of a transparent display apparatus according to an embodiment of the present disclosure.

FIG. 9 is a view illustrating dummy color patterns disposed in a pixel and a dummy pixel according to an embodiment of the present disclosure.

FIG. 10A is a cross-sectional view taken along line Ia-Ia′ of FIG. 9, and FIG. 10B is a cross-sectional view taken along line Ib-Ib′ of FIG. 9.

FIG. 11 is a view illustrating dummy color patterns disposed in a pixel and a dummy pixel according to an embodiment of the present disclosure.

FIG. 12 is a cross-sectional view taken along line II-II′ of FIG. 11.

FIG. 13 is another example of a cross-sectional view taken along line II-II′ of FIG. 11.

FIGS. 14A and 14B are cross-sectional views illustrating a structure of a part of a display area and a bezel area in a transparent display apparatus according to an embodiment of the present disclosure.

FIGS. 15A and 15B are cross-sectional views illustrating a structure of a part of a display area and a bezel area in a transparent display apparatus according to an embodiment of the present disclosure.

FIGS. 16A and 16B are cross-sectional views illustrating a structure of a part of a display area and a bezel area in a transparent display apparatus according to an embodiment of the present disclosure.

FIG. 17 is a plan view illustrating a pixel configuration of a transparent display apparatus according to an embodiment of the present disclosure.

FIG. 18 is a cross-sectional view taken along line III-III′ of FIG. 17.

FIG. 19 is a cross-sectional view taken along line IV-IV′ of FIG. 17.

### DETAILED DESCRIPTION OF THE EMBODIMENTS

The advantages and features of the present disclosure, and methods for achieving them, will become apparent with reference to the embodiments described below in detail in conjunction with the accompanying drawings. However, the present disclosure is not limited to the embodiments disclosed below and can be implemented in various different forms. These embodiments are merely provided so that the disclosure of the present disclosure will be complete and will fully convey the scope of the invention to those skilled in the art, and the present disclosure is defined only by the scope of the claims.

Shapes, sizes, ratios, angles, numbers, and the like disclosed in the drawings for describing embodiments of the present disclosure are illustrative, and the present disclosure is not limited to the matters shown in the drawings. Like reference numerals denote like elements throughout the disclosure. In addition, when it is determined that a detailed description of related well-known technology can unnecessarily obscure the subject matter of the present disclosure, the detailed description thereof will be omitted.

As used herein, when terms such as “comprises,” “has,” and “is formed of” are used, other parts can be added unless the term “only” is used. When an element is expressed in the singular, the singular includes the plural unless specifically stated otherwise.

In interpreting constituent elements, even if there is no separate explicit description of an error range, the element is interpreted as including an error range.

When a positional relationship is described, for example, when a positional relationship between two parts is described using terms such as “on,” “above,” “below,” and “next to,” one or more other parts can be positioned between the two parts unless the term “directly” or “immediately” is used.

When a temporal relationship is described, for example, when a temporal precedence relationship is described using terms such as “after,” “subsequent to,” “next,” and “before,” the relationship can include a non-continuous case unless the term “immediately” or “directly” is used.

Terms such as first and second are used to describe various components, but these components are not limited by these terms. These terms are used only to distinguish one component from another. Accordingly, a first component described below can also be a second component within the technical spirit of the present disclosure.

In describing constituent elements of the present disclosure, terms such as first, second, A, B, a, and b can be used. These terms are only for distinguishing the corresponding element from another element, and do not limit the nature, order, sequence, or number of the corresponding element.

When an element is described as being “connected,” “coupled,” or “linked” to another element, the element can be directly connected or linked to the other element, but it should also be understood that another element can be interposed between the elements unless explicitly stated otherwise. Further, the term “can” fully encompasses all the meanings and coverages of the term “may.”

“At least one” should be understood as including one or more combinations of the associated components. For example, the phrase “at least one of a first component, a second component, and a third component” can mean not only the first, second, or third component, but also any combination of two or more of the first, second, and third components.

The features of the various embodiments of the present disclosure can be partially or wholly combined or associated with each other, and can be technically interlocked and driven in various manners. The embodiments can be independently implemented, or can be implemented together in an associated relationship.

Hereinafter, embodiments of the present disclosure will be described with reference to the accompanying drawings and embodiments. All the components of each display apparatus/device according to all embodiments of the present disclosure are operatively coupled and configured. Further, since scales of constituent elements shown in the drawings are different from actual scales for convenience of description, the present disclosure is not limited to the scales shown in the drawings.

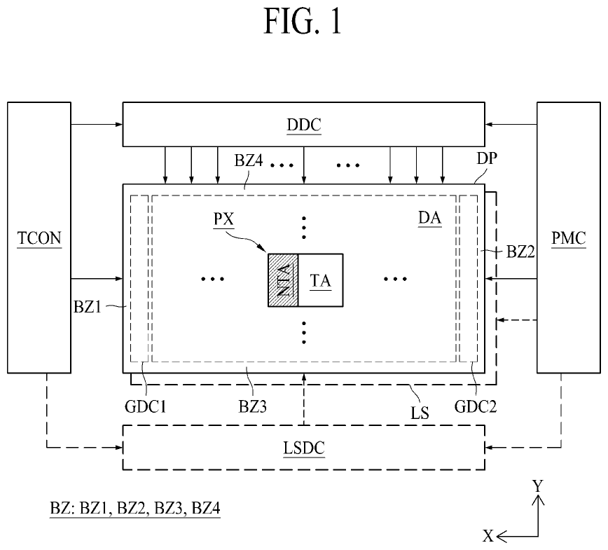

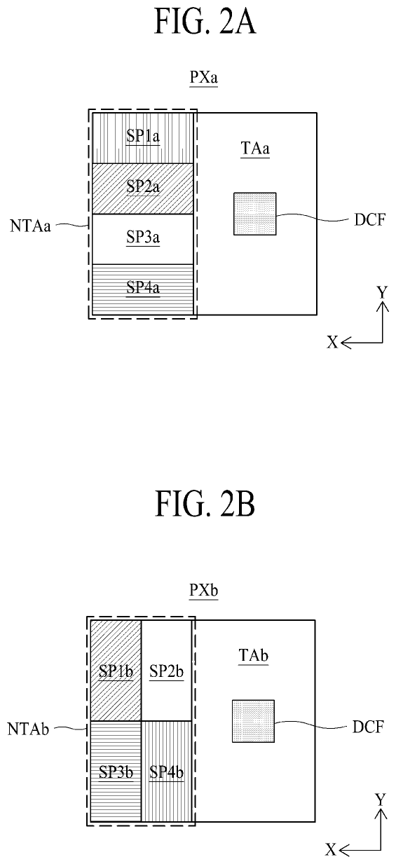

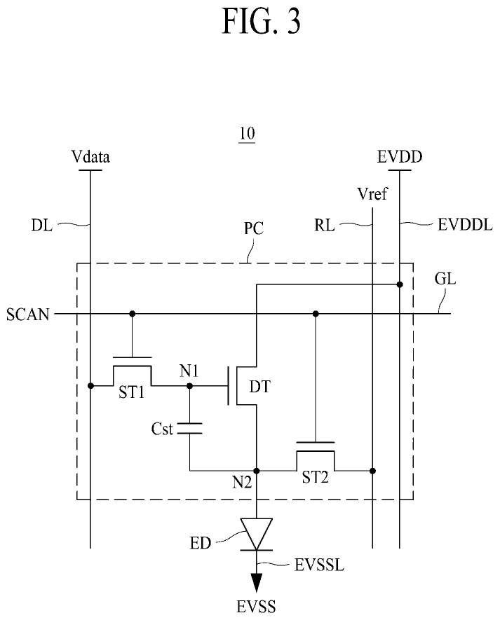

FIG. 1 is a block diagram schematically illustrating a configuration of a transparent display apparatus according to an embodiment of the present disclosure, FIGS. 2A and 2B are views schematically illustrating a pixel configuration of a transparent display apparatus according to an embodiment of the present disclosure, and FIG. 3 is an equivalent circuit diagram illustrating a configuration of a subpixel according to an embodiment of the present disclosure.

A transparent display apparatus according to an embodiment of the present disclosure can be an electroluminescence display apparatus using a self-emissive device. The electroluminescence display apparatus can include an organic light emitting diode OLED display apparatus, a quantum-dot light emitting diode display apparatus, an inorganic light emitting diode display apparatus, and a micro light emitting diode display apparatus.

Referring to FIG. 1, a transparent display apparatus according to an embodiment can include a transparent display panel DP, gate driving circuits GDC1 and GDC2, a data driving circuit DDC, a timing controller TCON, and a power management circuit PMC, but is not limited thereto and can further include other configurations. The gate driving circuits GDC1 and GDC2, the data driving circuit DDC, the timing controller TCON, and the power management circuit PMC can be referred to as display driving circuits.

In an embodiment of the present disclosure, the transparent display apparatus can further include an active light shielding plate LS disposed on a rear surface of the transparent display panel DP and a light shielding plate driving circuit LSDC for driving the active light shielding plate LS on/off according to a driving mode, but is not limited thereto, and the active light shielding plate LS and the light shielding plate driving circuit LSDC can be omitted.

The transparent display panel DP can be a rigid display panel or a flexible display panel capable of changing shape, such as a foldable, bendable, rollable, or stretchable display panel.

The transparent display panel DP can include a display area DA for displaying an image using a plurality of pixels PX arranged in a matrix form and a bezel area BZ located around the display area DA.

In the display area DA, each of the plurality of pixels PX can include a transmissive area TA through which light passes and a non-transmissive area NTA in which a plurality of subpixels for displaying an on-screen image are disposed.

The transmissive area TA is an area through which most of the light incident from the outside passes, and the non-transmissive area NTA is an area through which most of the light incident from the outside does not pass. The transmissive area TA can be an area having a light transmittance greater than t1%, and the non-transmissive area NTA can be an area having a light transmittance smaller than t2% (t1>t2). For example, the transmissive area TA can be an area having a light transmittance greater than 90%, and the non-transmissive area NTA can be an area having a transmittance smaller than 10%. The non-transmissive area NTA can be referred to as a light emitting area or a subpixel area, and the transmissive area TA can be referred to as a transparent area.

The transparent display panel DP can have a see-through characteristic in which a user can see a background located behind the transparent display panel DP through the transmissive areas TA.

In an embodiment of the present disclosure, the transparent display panel DP can further include a touch sensor screen embedded in or attached to overlap the display area DA to sense a user's touch.

The non-transmissive area NTA of each pixel PX can include a plurality of subpixels emitting light of different colors. The non-transmissive area NTA of each pixel PX can include three or four subpixels having different colors. In the non-transmissive area NTA, the four subpixels can be arranged in various forms such as a stripe type, a quad type, or a diamond type.

Each subpixel can include a light emitting element and a pixel circuit for independently driving the light emitting element. The light emitting element can be an organic light emitting diode, a quantum-dot light emitting diode, an inorganic light emitting diode, or a micro light emitting diode. The pixel circuit can include a plurality of thin film transistors (TFT) and at least one capacitor. The pixel circuit can be electrically connected to signal lines including a gate line, a data line, a reference line, a power line, and the like disposed in the transparent display panel DP.

The bezel area BZ of the transparent display panel DP can include first to fourth bezel areas BZ1 to BZ4 surrounding the periphery of the display area DA. The bezel area BZ can be a transparent bezel area through which light passes. The first and second bezel areas BZ1 and BZ2 can extend in a first direction Y and can be disposed side by side in a second direction X with the display area DA interposed therebetween. The third and fourth bezel areas BZ3 and BZ4 can extend in the second direction X and can be disposed side by side with the display area DA interposed therebetween.

At least one of the first and second bezel areas BZ1 and BZ2 can include at least one of the first and second gate driving circuits GDC1 and GDC2. The fourth bezel area BZ4 can include a pad area in which a plurality of signal pads are disposed. Among the bezel area BZ of the transparent display panel DP, at least the first to third bezel areas BZ1 to BZ3 can be transparent bezel areas, and the fourth bezel area BZ4 can be an opaque bezel area in which a black matrix is further disposed.

A light emitting layer of a light emitting element can be commonly disposed in the non-transmissive area NTA and the transmissive area TA of the display area DA of the transparent display panel DP, and the light emitting layer can extend into and be disposed up to an inner portion of the bezel area BZ adjacent to the display area DA. The light emitting layer extending to the bezel area BZ can have a form in which a thickness thereof decreases from an inner portion toward an outer portion of the bezel area BZ due to characteristics of a mask process.

The transparent display panel DP according to an embodiment of the present disclosure can include dummy pixels disposed in an inner portion of the bezel area BZ to which the light emitting layer extends. Each of the dummy pixels can include a non-transmissive area NTA and a transmissive area TA, similar to the pixel PX in the display area DA. A detailed description thereof will be given later.

Referring to FIGS. 1, 2A, and 2B, the transparent display apparatus according to an embodiment of the present disclosure can include a dummy color pattern DCF partially disposed in the transmissive areas TA, TAa, and TAb of the pixels PX, PXa, and PXb and the dummy pixels. The dummy color pattern DCF can be referred to as a color pattern or a color compensation pattern. The dummy color pattern DCF can alleviate a yellowish color caused by an organic material such as the light emitting layer in the transmissive area TA by compensating blue light using a blue color filter. A detailed description thereof will be given later.

In addition, in the transparent display apparatus according to an embodiment of the present disclosure, the area of the dummy color pattern DCF can gradually vary according to a thickness of the light emitting layer disposed in the bezel area BZ, thereby compensating for a color change according to the thickness of the light emitting layer. Accordingly, the transparent display apparatus according to an embodiment of the present disclosure can reduce or minimize a color difference in the bezel area BZ according to the presence or absence and thickness of the light emitting layer. A detailed description thereof will be given later.

Referring to FIG. 1, the gate driving circuits GDC1 and GDC2 can be disposed in the bezel areas BZ1 and BZ2 of the transparent display panel DP. The gate driving circuits GDC1 and GDC2 can be controlled according to a plurality of gate control signals supplied from the timing controller TCON, and can individually drive gate lines of the transparent display panel DP. The gate driving circuits GDC1 and GDC2 can be embedded in the bezel areas BZ1 and BZ2 of the transparent display panel DP in the form of Gate In Panel GIP formed together with TFTs of the display area DA.

The data driving circuit DDC can be controlled according to a data control signal supplied from the timing controller TCON, and can convert digital data supplied from the timing controller TCON into an analog data signal using a digital-to-analog conversion circuit. The data driving circuit DDC can convert digital data into an analog data signal using a plurality of gamma voltages and can supply the converted data signal to the data line of the transparent display panel DP.

The data driving circuit DDC can supply a reference voltage to the reference line of the transparent display panel DP under the control of the timing controller TCON.

The data driving circuit DDC according to an embodiment of the present disclosure can further include a sensing circuit. Under the control of the timing controller TCON, the data driving circuit DDC can sense a signal reflecting driving characteristics of each of the subpixels SP1 to SP4 through the reference line or the power line by a voltage sensing method or a current sensing method using the sensing unit.

The timing controller TCON can receive source image data and timing control signals from a host system. The host system can be any one of a computer, a TV system, a set-top box, a system of a portable terminal such as a tablet or a mobile phone, and a system inside a vehicle.

The timing controller TCON can control operations of the gate driving circuits GDC1, GDC2 and the data driving circuit DDC using timing control signals supplied from the host system and timing setting information stored therein.

In an embodiment of the present disclosure, the timing controller TCON can operate the transparent display apparatus in a sensing mode. In the sensing mode, the timing controller TCON can receive sensing data obtained by sensing electrical characteristics of each subpixel or a specific sensing area of the transparent display panel DP through a sensing circuit embedded in either the data driving circuit DDC or the power management circuit PMC.

The timing controller TCON can detect a change amount in electrical characteristics (threshold voltage shift value) of a driving transistor and/or a light emitting element of each subpixel based on the sensing data, can calculate a compensation value for compensating the same, and can store the compensation value in a memory. The timing controller TCON can compensate image data by applying the compensation value stored in the memory, thereby compensating luminance deviations due to characteristic deviations of each subpixel or afterimages due to degradation.

Additionally, the transparent display apparatus according to an embodiment of the present disclosure can operate in an on-screen priority mode and a see-through priority mode by controlling light transmittance of the active light shielding plate LS. The on-screen priority mode can include a normal display mode for displaying an image or the like. The see-through priority mode can include a transparent mode.

When the timing controller TCON controls the apparatus in the on-screen priority mode, the light shielding plate driver LSDC can drive the active light shielding plate LS in a light shielding mode for displaying black. Accordingly, the transparent display apparatus can improve visibility of an on-screen image by displaying the on-screen image using the subpixels of the non-transmissive area NTA on a black background of the active light shielding plate LS visible through the transmissive area TA of the transparent display panel DP.

When the timing controller TCON controls the apparatus in the see-through priority mode, the light shielding plate driver LSDC can drive the active light shielding plate LS in a transmission mode. Accordingly, the user can view an on-screen image displayed by the subpixels of the non-transmissive area NTA, together with a background visible through the transmissive area TA of the transparent display panel DP and the active light shielding plate LS.

The power management circuit PMC can generate and supply various driving voltages required for driving all components of the transparent display apparatus, for example, the transparent display panel DP, the gate driving circuits GDC1 and GDC2, the data driving circuit DDC, and the timing controller TCON, using an input voltage supplied from the outside. The power management circuit PMC can additionally generate and supply driving voltages required for driving the active light shielding plate LS and the light shielding plate driver LSDC.

Referring to FIG. 2A, each pixel PXa according to an embodiment of the present disclosure can include a non-transmissive area NTAa in which a plurality of subpixels SP1a, SP2a, SP3a, and SP4a are arranged in the first direction Y, and a transmissive area TAa directly adjacent to the non-transmissive area NTAa in the second direction X. This pixel PXa structure can be equally applied to each pixel in the display area DA and to dummy pixels in the bezel area BZ.

The first to fourth subpixels SP1a to SP4a can include a red (hereinafter, R) subpixel emitting red light, a green (hereinafter, G) subpixel emitting green light, a blue (hereinafter, B) subpixel emitting blue light, and a white (hereinafter, W) subpixel emitting white light. For example, the first to fourth subpixels SP1a to SP4a can respectively correspond to subpixels arranged in the order of R/G/B/W, W/R/G/B, R/W/B/G, R/W/G/B, G/W/B/R, R/G/W/B, or B/W/G/R in the first direction Y, but are not limited thereto.

Referring to FIG. 2B, each pixel PXb according to an embodiment of the present disclosure can include a non-transmissive area NTAb in which a plurality of subpixels SP1b, SP2b, SP3b, and SP4b are arranged in a quad type, and a transmissive area TAb directly adjacent to the non-transmissive area NTAb in the second direction X. This pixel PXb structure can be equally applied to each pixel in the display area DA and to dummy pixels in the bezel area BZ.

In the non-transmissive area NTAb, first and second subpixels SP1b and SP2b of a first row line can be disposed adjacent to each other in the second direction X, and third and fourth subpixels SP3b, SP4b of a second row line can be disposed adjacent to each other in the second direction X. The first and second subpixels SP1b, SP2b of the first row line and the third and fourth subpixels SP3b, SP4b of the second row line can be disposed adjacent to each other in the first direction Y. The first to fourth subpixels SP1b to SP4b can respectively correspond to subpixels arranged in the order of R/G/B/W, W/R/G/B, R/W/B/G, R/W/G/B, G/W/B/R, R/G/W/B, or B/W/G/R, but are not limited thereto.

Referring to FIGS. 2A and 2B, the transmissive areas TAa and TAb of each pixel PXa and PXb can include a dummy color pattern DCF for compensating for a color change caused by the light emitting layer. The dummy color pattern DCF can be formed of the same blue color filter as the blue subpixel in order to neutralize a yellowish color caused by the light emitting layer disposed in the transmissive areas TAa and TAb, but is not limited thereto and can be formed of a color filter of another color. The dummy color pattern DCF can be disposed in a partial area of the transmissive areas TAa and TAb. The area of the dummy color pattern DCF is smaller than the area of each of the transmissive areas TAa and TAb of the pixels PXa and PXb, and can have an area capable of preventing a change to a bluish color due to the dummy color pattern DCF. A detailed description thereof will be given later.

Referring to FIG. 3, each subpixel 10A can include a light emitting element ED connected between a first power line EVDDL supplying a high-level power voltage ELVDD (first power voltage) and a second power line EVSSL supplying a low-level power voltage ELVSS (second power voltage), and a pixel circuit PC including first and second switching TFTs ST1, ST2, a driving TFT DT, and a storage capacitor Cst to independently drive the light emitting element ED.

The light emitting element ED can include an anode connected to a source node N2 of the driving TFT DT, a cathode connected to the second power line EVSSL, and an organic light emitting layer between the anode and the cathode. The anode can be independent for each subpixel, but the cathode can be a common electrode shared by all subpixels. When a driving current is supplied from the driving TFT DT, electrons from the cathode are injected into the organic light emitting layer and holes from the anode are injected into the organic light emitting layer, so that fluorescent or phosphorescent material emits light through recombination of electrons and holes in the organic light emitting layer, thereby generating light having luminance proportional to an amount of the driving current.

The first switching TFT ST1 is driven by a scan signal SCAN supplied to a gate line GL from the gate driving circuits GDC1 and GDC2, and can supply a data voltage Vdata supplied to a data line DL from the data driving circuit DDC to a gate node N1 of the driving TFT DT.

The second switching TFT ST2 is driven by the scan signal SCAN supplied to the gate line GL from the gate driving circuits GDC1 and GDC2, and can supply a reference voltage Vref supplied to the reference line RL from the data driving circuit DDC to the source node N2 of the driving TFT DT. Meanwhile, in a sensing mode, the second switching TFT ST2 can provide, to the reference line RL, a current reflecting characteristics of the driving TFT DT or characteristics of the light emitting element ED.

The storage capacitor Cst connected between the gate node N1 and the source node N2 of the driving TFT DT can charge, as a target driving voltage Vgs of the driving TFT DT, a difference voltage between the data voltage Vdata and the reference voltage Vref supplied respectively to the gate node N1 and the source node N2 through the first and second switching TFTs ST1 and ST2, and can hold the charged driving voltage Vgs during an emission period in which the first and second switching TFTs ST1 and ST2 are turned off.

The driving TFT DT can control an amount of current Ids flowing to the light emitting element ED according to the target driving voltage Vgs charged in the storage capacitor Cst, thereby controlling emission intensity of the light emitting element ED.

In FIG. 3, the gate line GL can be driven by the gate driving circuits GDC1 and GDC2, can receive the data voltage Vdata and the reference voltage Vref from the data driving circuit DDC, and can receive the high-level power voltage ELVDD and the low-level power voltage ELVSS from the power management circuit PMC.

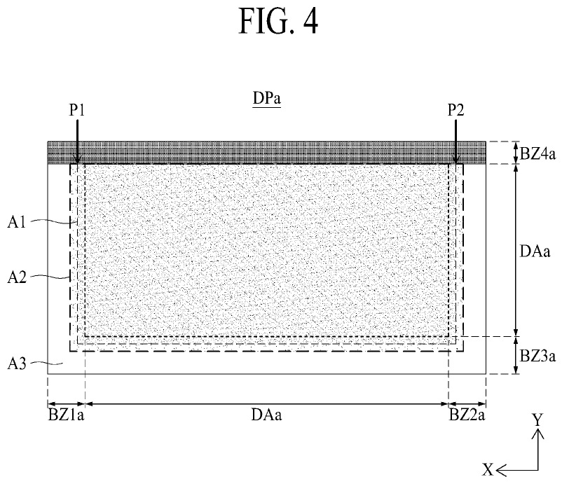

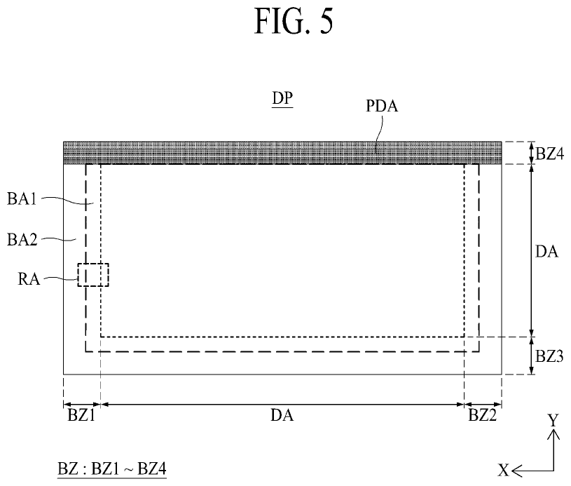

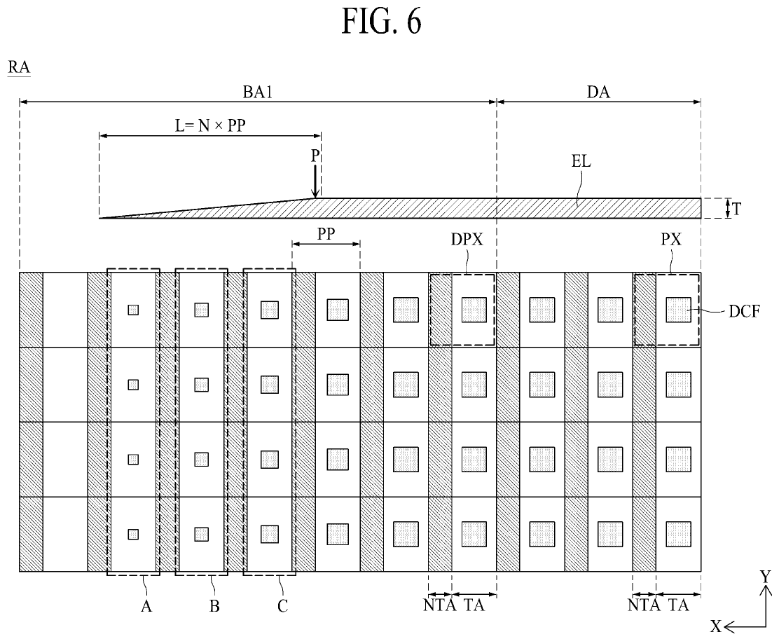

FIG. 4 is a view illustrating a color-difference phenomenon of a transparent display panel according to a comparative example of the present disclosure, FIG. 5 is a view schematically illustrating a transparent display panel according to an embodiment of the present disclosure, and FIG. 6 is an enlarged view of portion RA in the transparent display panel according to the embodiment shown in FIG. 5.

Referring to FIG. 4, in the transparent display panel DPa according to the comparative example, the display area DAa and first and second areas A1, A2 of transparent bezel areas BZ1a to BZ3a among bezel areas BZ1a, BZ2a, BZ3a, and BZ4a can exhibit a yellowish color due to an organic material of a light emitting layer (emission stack) present in the transmissive area, and can exhibit a color difference from a third area A3 of the transparent bezel areas BZ1a to BZ3a in which no light emitting layer is present. In addition, when the light emitting layer is formed, a shadowing phenomenon of a mask can occur at an edge area so that a thickness of the light emitting layer in the second area A2 of the transparent bezel areas BZ1a to BZ3a can gradually decrease toward the third area A3. Accordingly, a greater color difference can appear between the first and second areas A1 and A2 having different thicknesses of the light emitting layer.

Referring to FIGS. 5 and 6, the transparent display panel DP according to an embodiment of the present disclosure can include a plurality of pixels PX disposed in the display area DA and dummy pixels DPX disposed in a first area BA1 adjacent to the display area DA among bezel areas BZ1 to BZ4. The pixels PX and the dummy pixels DPX can include a non-transmissive area NTA in which subpixels are disposed and a transmissive area TA, and can include a dummy color pattern DCF disposed in a partial area of each transmissive area TA. The bezel areas BZ1 to BZ4 can include transparent bezel areas BZ1 to BZ3 and an opaque bezel area BZ4 having a pad area PDA.

A light emitting layer EL can be commonly disposed in the non-transmissive area NTA and the transmissive area TA of the pixels PX and the dummy pixels DPX. As described above, it can be seen that the light emitting layer EL has a form in which a thickness T thereof gradually decreases in the first area BA1 corresponding to an edge area due to a mask shadowing phenomenon.

The transparent display panel DP according to an embodiment of the present disclosure can be configured such that, in the first area BA1 of the transparent bezel areas BZ1 to BZ3, the area of the dummy color pattern DCF disposed in each transmissive area TA of the dummy pixels DPX gradually varies according to a change in the thickness T of the light emitting layer EL.

Accordingly, it is possible to reduce or minimize a color difference according to a change in the thickness T of the light emitting layer EL in the first area BA1 of the transparent bezel areas BZ1 to BZ3 corresponding to the edge area of the light emitting layer EL.

Accordingly, it is possible to reduce or minimize a color difference between the display area DA and the first area BA1 of the transparent bezel areas BZ1 to BZ3, where the light emitting layer EL is present, and the second area BA2 of the transparent bezel areas BZ1 to BZ3, where no light emitting layer EL is present.

Furthermore, it is possible to reduce or minimize a color difference between the display area DA and the transparent bezel areas BZ1 to BZ3.

In the transparent display panel DP according to an embodiment of the present disclosure, the thickness T of the light emitting layer EL and the area of the dummy color pattern DCF can have a proportional relationship. As the thickness T of the light emitting layer EL decreases, the area of the dummy color pattern DCF can decrease.

For example, as shown in FIG. 6, when a length (L=N*PP) in the second direction X, over which the thickness of the light emitting layer changes in the first area BA1 of the bezel area BZ, is approximately equal to a pixel pitch PP of N dummy pixels DPX, the amount of change in the area of the dummy color pattern DCF can be determined as in Equation 1 below, but is not limited thereto.

$$the amount of change in the area of DCF = \frac{the area of the DCF ∈ DA ( \% )}{N + 1} \qquad 〈 Equation 1 〉$$

Referring to Equation 1, in the first area BA1 of the bezel area BZ, an amount of change (%) in the area of the dummy color pattern DCF can be determined as a result obtained by dividing the area (area ratio %) of the dummy color pattern DCF in the transmissive area TA of the display area DA by the number (N)+1 of dummy pixels DPX in the second direction X, in which the thickness T of the light emitting layer EL decreases.

For example, referring to FIG. 6, the transparent display panel DP according to an embodiment of the present disclosure can include dummy pixels DPX of first to third columns A, B, and C, for example, three dummy pixels DPX in the second direction X, in which the thickness T of the light emitting layer EL decreases in the first area BA1 of the bezel area BZ, but is not limited thereto.

For example, when an area (%) of the dummy color pattern DCF in the transmissive area TA of the pixel PX in the display area DA is 10%, and a length L over which the thickness T of the light emitting layer EL decreases in the first area BA1 of the bezel area BZ is approximately equal to a pitch in the second direction X of dummy pixels DPX of three columns A, B, and C (3*PP=L, N=3), an amount of change (%) in the area of the dummy color pattern DCF can be determined to be 2.5%.

Accordingly, the area (%) of the dummy color pattern DCF in the transmissive area TA of the first column A can be 2.5%, the area (%) of the dummy color pattern DCF in the transmissive area TA of the second column B can be 5%, and the area (%) of the dummy color pattern DCF in the transmissive area TA of the third column C can be 7.5%.

The dummy color pattern DCF may not be disposed in the transmissive portion TA of at least one column of dummy pixels DPX positioned at the outermost side in the first area BA1 of the bezel area BZ.

In the transparent display panel DP according to an embodiment of the present disclosure, the area (%) of the dummy color pattern DCF in the transmissive area TA of the pixel PX in the display area DA can be determined at a level at which it is difficult for a user to recognize a color change caused by the dummy color pattern DCF.

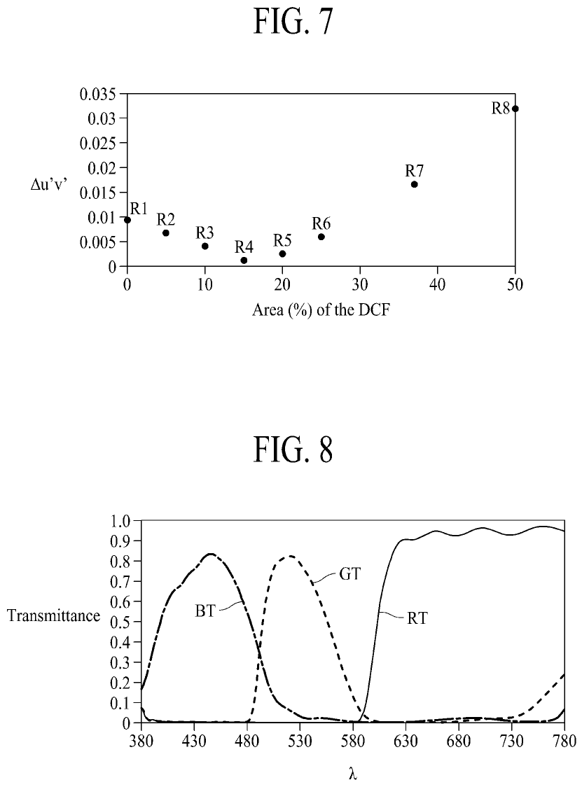

FIG. 7 is a graph showing a relationship between an area of a dummy color pattern and a color difference in a transparent display apparatus according to an embodiment of the present disclosure, and FIG. 8 is a graph showing transmittances of R/G/B light in a transmissive portion of a transparent display apparatus according to an embodiment of the present disclosure.

Referring to FIG. 7, it can be seen that a color difference Δu′v′ linearly varies according to an area (area ratio %) of the dummy blue pattern DCF added to each transmissive area TA. Here, the color difference Δu′v′ means a difference between a color emitted from a light source itself and a color changed after passing through the transparent display panel from the light source.

In detail, when the dummy blue pattern DCF is added to each transmissive area TA, the color difference Δu′v′ decreases compared with a case in which no dummy blue pattern DCF is present, and it can be seen that, as the area (area ratio %) of the dummy blue pattern DCF increases, the color difference Δu′v′ greatly decreases and then, when the area exceeds a certain value, the color difference Δu′v′ tends to increase again. This indicates that a yellowish color of the transmissive area TA changes toward a neutral color as the area of the dummy blue pattern DCF increases, but when the area of the dummy blue pattern DCF increases beyond a certain value, the color difference Δu′v′ due to the dummy blue pattern DCF increases, so that the transmissive area TA can change to a bluish color. In consideration of this, the area (area ratio) of the dummy blue pattern DCF in the transmissive area TA of each of the pixels PX and DPX can be determined, for example, within a range of 5% to 25% in which the color difference Δu′v′ is 0.006 or less, which is difficult to perceive, but is not limited thereto.

In the transparent display apparatus according to the comparative example, a yellowish color caused by the light emitting layer in the transmissive area TA of each of the pixels PX and DPX can occur because transmittance of blue light in a short-wavelength range, for example, a wavelength range of 380 nm or more and less than 500 nm, decreases.

In the transparent display apparatus according to an embodiment of the present disclosure, it can be seen that, due to the dummy blue pattern DCF additionally provided in the transmissive area TA of each of the pixels PX and DPX, as shown in FIG. 8, blue light transmittance BT is compensated similarly to green light transmittance GT and red light transmittance RT.

Accordingly, in the transparent display apparatus according to an embodiment of the present disclosure, the yellowish color can be reduced or minimized by the dummy blue pattern DCF additionally provided in the transmissive area TA of each of the pixels PX and DPX.

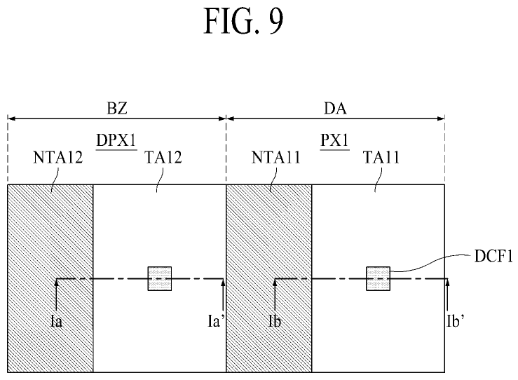

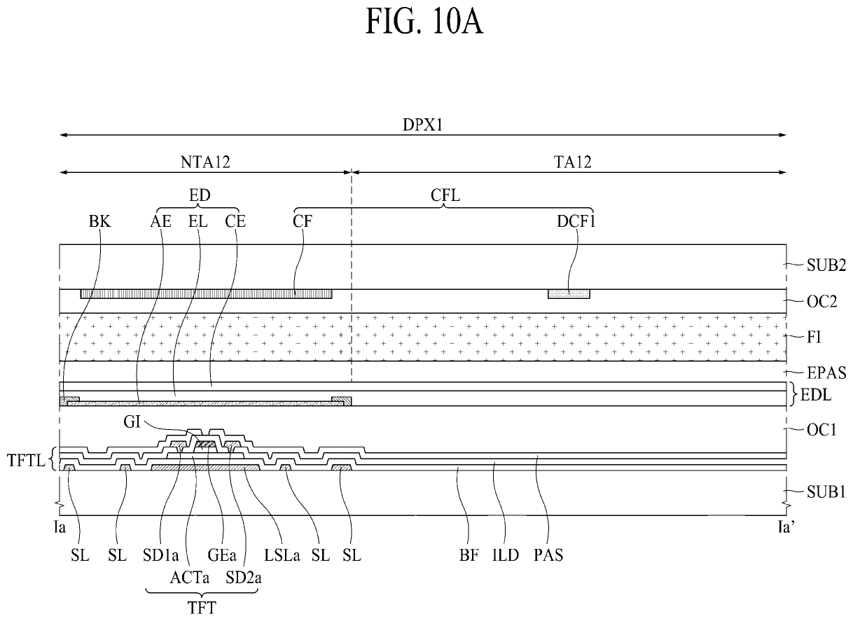

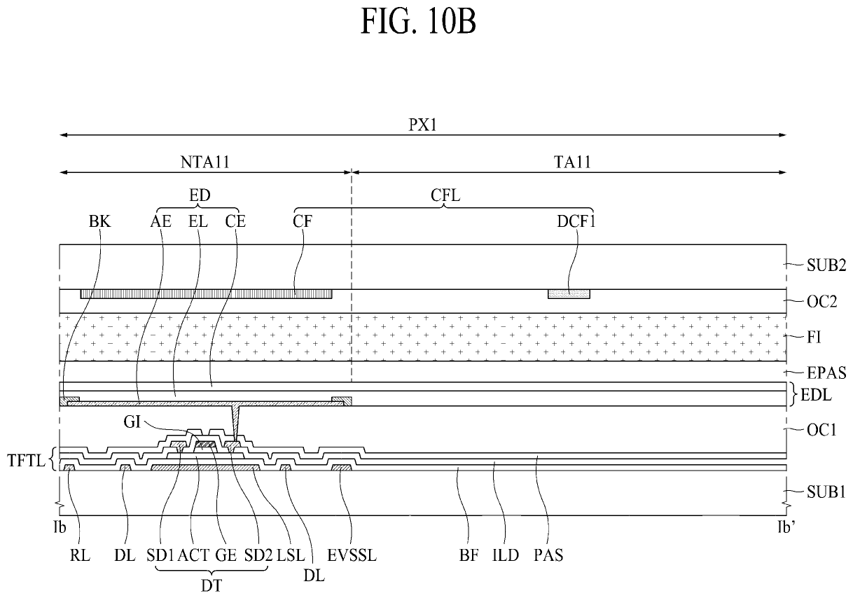

FIG. 9 is a view illustrating a dummy color pattern disposed in a pixel and a dummy pixel according to an embodiment of the present disclosure, FIG. 10A is a cross-sectional view taken along line Ia-Ia′ of FIG. 9, and FIG. 10B is a cross-sectional view taken along line Ib-Ib′ of FIG. 9.

Referring to FIGS. 9 to 10B, the transparent display apparatus according to an embodiment of the present disclosure can include a pixel PX1 disposed in the display area DA and a dummy pixel DPX1 disposed in the bezel area BZ. The pixel PX1 in the display area DA and the dummy pixel DPX1 in the bezel area BZ can include non-transmissive areas NTA11 and NTA12 in which first to fourth subpixels are disposed and transmissive areas TA11 and TA12. Each of the transmissive area TA11 (first transmissive area) of the pixel PX1 and the transmissive area TA12 (second transmissive area) of the dummy pixel DPX1 in the bezel area BZ can include a dummy color pattern DCF1 disposed at a central portion thereof.

Referring to FIGS. 10A and 10B, the transparent display apparatus according to an embodiment of the present disclosure can include a circuit element layer TFTL, an overcoat layer OC1, a light emitting element layer EDL, an encapsulation layer EPAS, a filling layer FI, an overcoat layer OC2, and a color filter layer CFL, which are stacked between a first substrate SUB1 and a second substrate SUB2. The first substrate SUB1 on which the circuit element layer TFTL, the overcoat layer OC1, the light emitting element layer EDL, and the encapsulation layer EPAS are stacked can be referred to as an element substrate or a first substrate SUB1 on which circuit elements and light emitting elements are disposed. The second substrate SUB2 on which the color filter layer CFL and the overcoat layer OC2 are disposed can be referred to as a color filter substrate or a second substrate SUB2 on which color filters are disposed. The element substrate and the color filter substrate can be bonded together with the filling layer FI and a dam member interposed therebetween.

The first substrate SUB1 can be made of glass or plastic. The first substrate SUB1 can include transparent plastic having a flexible property, for example, at least one organic insulating material selected from acrylic resin, epoxy resin, siloxane resin, polyimide resin, and polyamide resin. In an embodiment of the present disclosure, the first substrate SUB1 can have a stacked structure of upper and lower polyimide layers with an inorganic insulating layer interposed therebetween.

The circuit element layer TFTL on the first substrate SUB1 can include a pixel circuit PC (in FIG. 3) of each subpixel disposed in the non-transmissive area NTA11 of each pixel PX in the display area DA, and gate driving circuits GDC1 and GDC2 (in FIG. 1) disposed in the dummy pixel DPX1 in the bezel area BZ. The gate driving circuits GDC1 and GDC2 (in FIG. 1) can overlap the non-transmissive area NTA12 (in second non-transmissive area) of the dummy pixel DPX1.

The gate driving circuits GDC1 and GDC2 (in FIG. 1), disposed to overlap the non-transmissive area NTA12 of the dummy pixel DPX1 in the bezel area BZ, can include a plurality of thin film transistors TFT and a plurality of signal lines SL disposed on the first substrate SUB1. Each thin film transistor TFT can include an active layer ACTa, a gate electrode GEa, and first and second source-drain electrodes SD1a and SD2a, and can further include a light shielding electrode LSLa overlapping the active layer ACTa thereunder. The plurality of signal lines SL can be disposed on the same layer as the light shielding metal LSLa, or on the same layer as the gate electrode GEa or the source-drain electrodes SD1a and SD2a.

In the display area DA, the pixel circuit PC (in FIG. 3) disposed to overlap the non-transmissive area NTA11 of the pixel PX1 can include a driving transistor DT and a plurality of signal lines (RL, DL, EVSSL, etc.) disposed on the first substrate SUB1. The driving transistor DT can include an active layer ACT, a gate electrode GE, and first and second source-drain electrodes SD1 and SD2, and can further include a light shielding electrode LSL overlapping the active layer ACT thereunder. The plurality of signal lines (RL, DL, EVSSL, etc.) can be disposed on the same layer as the light shielding metal LSL, or on the same layer as the gate electrode GEa or the source-drain electrodes SD1a and SD2a.

The circuit element layer TFTL can include a buffer layer BF covering the light shielding electrodes LSLa and LSL disposed on the first substrate SUB1, and the active layers ACTa and ACT can be disposed on the buffer layer BF. A gate insulating layer GI and gate electrodes GE can be stacked on the active layers ACTa and ACT. An interlayer insulating layer ILD covering the active layer ACTa, the gate insulating layer GI, and the gate electrode GE can be disposed thereon.

First and second source-drain electrodes SD1a, SD1, SD2a, and SD2 can be disposed on the interlayer insulating layer ILD. The first and second source-drain electrodes SD1a and SD2a of the thin film transistor TFT can be connected to first and second conductive regions of the active layer ACTa, respectively, through contact holes passing through the interlayer insulating layer ILD. The first and second source-drain electrodes SD1 and SD2 of the driving transistor DT can be connected to first and second conductive regions of the active layer ACT, respectively, through contact holes passing through the interlayer insulating layer ILD.

A passivation layer PAS covering the first and second source-drain electrodes SD1a, SD1, SD2a, and SD2 can be disposed.

The circuit element layer TFTL can be covered by an overcoat layer OC1, which is a planarization layer. The overcoat layer OC1 can be referred to as a planarization layer or an organic insulating layer. The overcoat layer OC1 can include an organic insulating material. For example, the overcoat layer OC1 can include at least one organic insulating material selected from acrylic resin, epoxy resin, siloxane resin, polyimide resin, and polyamide resin.

The light emitting element layer EDL on the overcoat layer OC1 can include a plurality of light emitting elements ED disposed in the non-transmissive areas NTA11 and NTA12 of the pixel PX1 and the dummy pixel DPX1. In the non-transmissive area NTA11 of each pixel PX1, the light emitting elements ED can be disposed to overlap each pixel circuit PC (FIG. 3) of the circuit element layer TFTL and can be connected to the driving transistor DT of each pixel circuit PC. In the non-transmissive area NTA12 of the dummy pixel DPX1, the light emitting elements ED can be disposed to overlap the gate driving circuits GDC1 and GDC2 (in FIG. 1). The light emitting elements ED disposed in the non-transmissive area NTA12 of the dummy pixel DPX1 can be in an off state without emission, without being connected to TFTs of the gate driving circuits GDC1 and GDC2.

The light emitting element ED can include a first electrode (hereinafter, anode electrode) AE disposed on the overcoat layer OC1, a bank insulating layer BK covering an edge of the anode electrode AE, a light emitting layer (emission stack) EL on the anode electrode AE and the bank insulating layer BK, and a second electrode (hereinafter, cathode electrode) CE on the light emitting layer EL. The anode electrode AE and the bank insulating layer BK can be disposed only in the non-transmissive areas NTA11 and NTA12 of the pixel PX1 and the dummy pixel DPX1, whereas the light emitting layer EL and the cathode electrode CE can be commonly disposed over the non-transmissive areas NTA11 and NTA12 and the transmissive areas TA11 and TA12 of the pixel PX1 and the dummy pixel DPX1.

The anode electrode AE can be independently disposed in an emission area of each subpixel. The anode electrode AE can be connected to the driving transistor DT of the circuit element layer TFTL through a contact hole formed in the overcoat layer OC1. The anode electrode AE can be formed of a stacked structure of a plurality of conductive layers having high reflectivity. For example, the anode electrode AE can be formed of a stacked structure of aluminum (Al) and titanium (Ti) (Ti/Al/Ti), a stacked structure of aluminum (Al) and ITO (Indium Tin Oxide) (ITO/Al/ITO), or a stacked structure of APC (Ag—Pd—Cu alloy) and ITO (ITO/APC/ITO).

The bank insulating layer BK can be formed in a structure covering an edge of the anode electrode AE to define an emission area of each light emitting element ED. The bank insulating layer BK can be formed in a single layer or double layer structure including an organic insulating material. The bank insulating layer BK can include at least one of a black material, a light shielding material, and alight absorbing material, thereby blocking light leakage between adjacent subpixels and reducing external light reflection.

The light emitting layer EL can be formed on the anode electrode AE, the bank insulating layer BK, and the overcoat layer OC1. The light emitting layer EL can be configured as an emission stack in which at least two stacks are stacked to emit white light, but is not limited thereto and can emit light of various colors. Each stack can have a structure in which a hole control layer, an emission layer, and an electron control layer are stacked, and can be stacked with a charge generation layer interposed therebetween. The hole control layer can include at least a hole transport layer among a hole injection layer and a hole transport layer, and the electron control layer can include at least an electron transport layer among an electron transport layer and an electron injection layer. For example, the light emitting layer EL can include a first stack including a blue emission layer, a second stack including a yellow-green emission layer, a third stack including a blue emission layer, a first charge generation layer between the first and second stacks, and a second charge generation layer between the second and third stacks, but is not limited thereto.

A cathode electrode CE can be formed on the light emitting layer EL. The cathode electrode CE can be formed of a conductive material having high light transmittance or a semi-transmissive conductive material. For example, the cathode electrode CE can be formed of a transparent conductive material such as ITO or IZO. The cathode electrode CE can be formed of a semi-transmissive metal material such as magnesium (Mg), silver (Ag), or an alloy thereof. In an embodiment of the present disclosure, a capping layer can be further disposed on the cathode electrode CE to improve optical resonance and luminous efficiency of the light emitting element ED.

An encapsulation layer EPAS can be disposed on the light emitting element layer EDL to prevent moisture or oxygen from penetrating into the light emitting element ED. The encapsulation layer EPAS can be formed in a single layer structure or a multi-layer stacked structure including at least one of an inorganic insulating material and an organic insulating material.

The second substrate SUB2 can be made of glass or plastic. The second substrate SUB2 can include transparent plastic having a flexible property, for example, at least one organic insulating material selected from acrylic resin, epoxy resin, siloxane resin, polyimide resin, and polyamide resin.

On an inner surface of the second substrate SUB2 facing the first substrate SUB1, a color filter layer CFL including color filters CF and dummy color filters DCF can be disposed, and an overcoat layer OC2 covering the color filter layer CFL can be disposed. The color filter layer CFL can further include a black matrix.

The color filter layer CFL can include a plurality of color filters CF disposed to overlap light emitting elements ED of respective subpixels in the non-transmissive portions NTA11, NTA12 of the pixel PX1 and the dummy pixel DPX1, the plurality of color filters respectively transmitting light of different colors. For example, the color filter layer CFL can include a first color filter CF overlapping the light emitting element ED of a first subpixel and transmitting red light, a second color filter CF overlapping the light emitting element ED of a second subpixel and transmitting green light, and a third color filter CF overlapping the light emitting element ED of a third subpixel and transmitting blue light.

The color filter layer CFL can further include a black matrix disposed in the non-transmissive portions NTA11 and NTA12 of the pixel PX1 and the dummy pixel DPX1 to overlap edge portions of the color filters CF and to overlap the bank insulating layer BK. The black matrix can block light leakage between adjacent subpixels and reduce external light reflection. The black matrix can be omitted when the bank insulating layer BK is made of a black material.

The color filter layer CFL can include a dummy color pattern DCF1 partially disposed in the transmissive portions TA11 and TA12 of the pixel PX1 and the dummy pixel DPX1 to compensate for a reduction in transmittance of light in a short-wavelength band, which causes a color change (yellowishness) in the transmissive portions TA11 and TA12. For example, the dummy color pattern DCF1 can be a dummy blue pattern (blue compensation pattern) for compensating transmittance of blue light, which causes the yellowish color of the transmissive portions TA11 and TA12, and can be formed in the same process as the blue color filter CF.

The dummy color pattern DCF1 can be disposed in a square shape at a central portion of each of the transmissive portions TA11 and TA12 of the pixel PX1 and the dummy pixel DPX1, but is not limited thereto. The dummy color pattern DCF1 can have various shapes such as a circular shape or a polygonal shape and can be disposed at various positions of the transmissive portions TA11 and TA12.

In the bezel area BZ, the dummy color pattern DCF1 can have a form in which the area of the dummy color pattern DCF1 decreases as the thickness of the light emitting layer EL or the light emitting element layer EDL decreases, in proportion to the thickness of the light emitting layer EL or the light emitting element layer EDL, as described with reference to FIG. 6.

Between the element substrate, in which the circuit element layer TFTL, the overcoat layer OC1, the light emitting element layer EDL, and the encapsulation layer EPAS are stacked on the first substrate SUB1, and the color filter substrate, in which the color filter layer CFL and the overcoat layer OC2 are stacked on the second substrate SUB2, a filling layer FI filling a gap between the element substrate and the color filter substrate can be disposed. The filling layer FI can be made of a transparent material and can have a barrier function of preventing penetration of oxygen/moisture. The filling layer FI can further include a getter absorbing oxygen/moisture. The filling layer FI can include a transparent adhesive material and can serve to bond the element substrate and the color filter substrate together along with a dam member surrounding an edge area of the bezel area BZ.

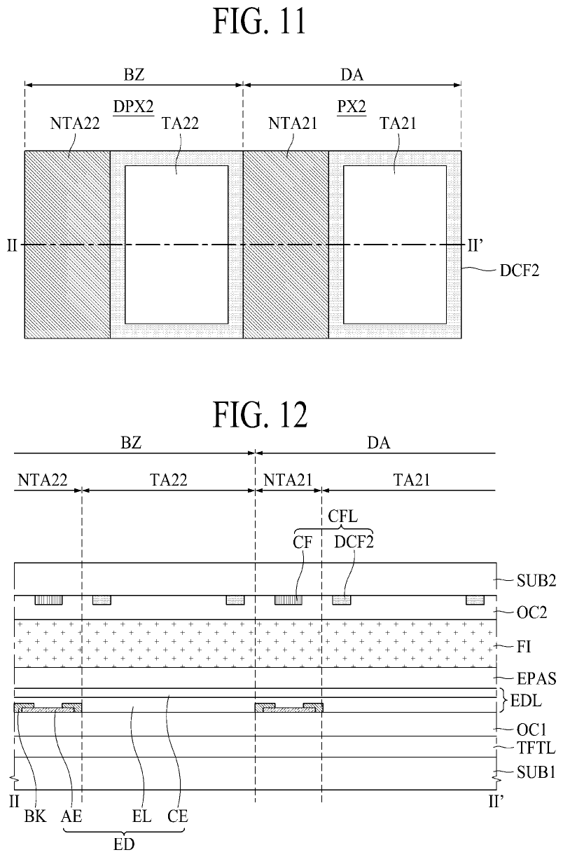

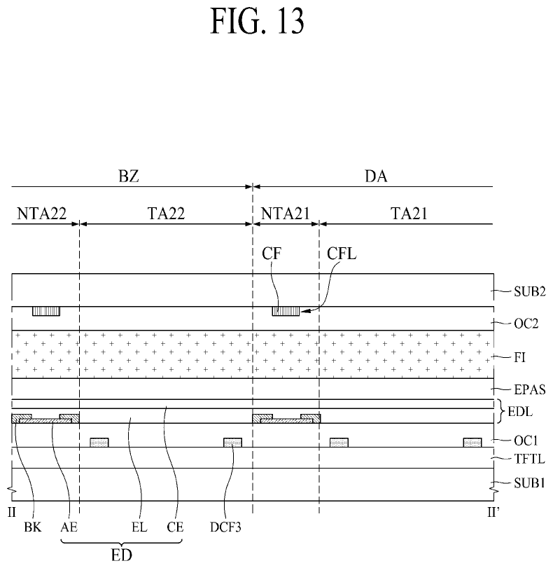

FIG. 11 is a view illustrating a dummy color pattern disposed in a pixel and a dummy pixel according to an embodiment of the present disclosure, FIG. 12 is a cross-sectional view taken along line II-II′ of FIG. 11, and FIG. 13 is another example of a cross-sectional view taken along line II-II′ of FIG. 11.

Whereas the transparent display apparatus according to the embodiment of the present disclosure shown in FIGS. 9 and 10 described above includes the dummy color patterns DCF1 respectively disposed at central portions of the transmissive portions TA11 and TA12 of the pixel PX1 and the dummy pixel DPX1, the transparent display apparatus according to the embodiment of the present disclosure shown in FIGS. 11 to 13 is different in that it includes dummy color patterns DCF2 having a form surrounding edge portions of transmissive portions TA21 and TA22 of a pixel PX2 and a dummy pixel DPX2. Therefore, the following description will focus on the above differences, and descriptions of configurations overlapping those of FIGS. 9 and 10 will be omitted or briefly mentioned.

Referring to FIGS. 11 to 13, the dummy color patterns DCF2 respectively disposed in the transmissive portion TA21 of the pixel PX2 in the display area DA and the transmissive portion TA22 of the dummy pixel DPX2 in the bezel area BZ can have a band shape or a closed-loop shape surrounding an edge of each of the transmissive portions TA21 and TA22.

In the bezel area BZ, the dummy color pattern DCF2 can have a form in which an area of the dummy color pattern DCF2 decreases as the thickness of the light emitting layer EL decreases, in proportion to the thickness of the light emitting layer EL or the light emitting element layer EDL, as described with reference to FIG. 6.

Referring to FIGS. 11 and 12, the dummy color pattern DCF2 can be located on the same layer as the color filter CF formed on the second substrate SUB2, and can be a dummy blue pattern (blue compensation pattern) formed in the same process as the blue color filter CF.

Referring to FIGS. 11 and 13, the dummy color pattern DCF2 can be disposed on the circuit element layer TFTL of the first substrate SUB1, and the dummy color pattern DCF2 formed on the circuit element layer TFTL can be covered by the overcoat layer OC1. The dummy color pattern DCF2 can be a dummy blue pattern (blue compensation pattern) that transmits blue light.

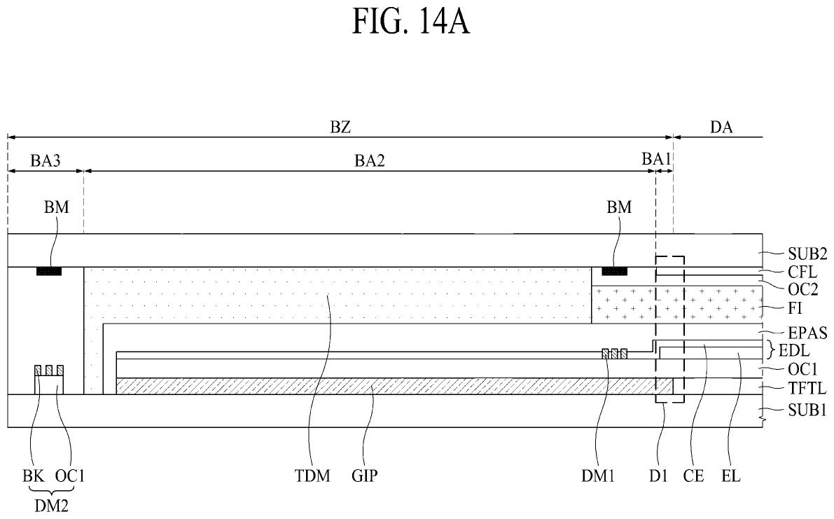

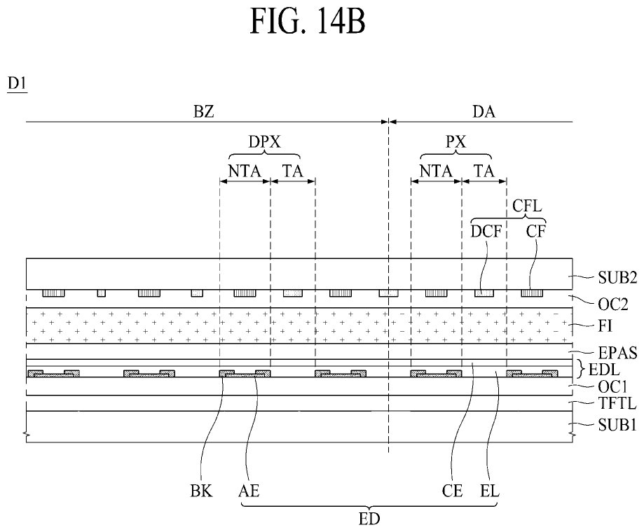

FIG. 14A is a cross-sectional view illustrating a structure of a part of a display area and a bezel area in a transparent display apparatus according to an embodiment of the present disclosure, and FIG. 14B is an enlarged view of portion D1 shown in FIG. 14A.

Referring to FIGS. 14A and 14B, the transparent display apparatus according to an embodiment of the present disclosure can include a filling layer FI disposed between a first substrate SUB1 on which a circuit element layer TFTL, an overcoat layer OC1, a light emitting element layer EDL, and an encapsulation layer EPAS are sequentially stacked and a second substrate SUB2 on which a color filter layer CFL and an overcoat layer OC2 are stacked. The first substrate SUB1 on which circuit elements TFTL and the light emitting element layer EDL are disposed and the second substrate SUB2 on which the color filter layer CFL is disposed can be bonded together by a dam member TDM disposed in the bezel area BZ. The first substrate SUB1 on which circuit elements TFTL and the light emitting element layer EDL are disposed and the second substrate SUB2 on which the color filter layer CFL is disposed can be bonded together by the dam member TDM disposed in the bezel area BZ and the filling layer FI disposed in the display area DA and a part of the bezel area BZ.

The bezel area BZ can include a first area BA1 in which dummy pixels DPX are disposed, a second area BA2 in which the dam member TDM is disposed, and a third area BA3 located outside the second area BA2.

The dam member TDM can be made of a transparent adhesive to bond the first substrate SUB1 and the second substrate SUB2 together and to make the bezel area BZ appear transparent. The dam member TDM can further include a getter absorbing moisture or oxygen. In the second area BA2 of the bezel area BZ, the dam member TDM can be bonded while contacting the first substrate SUB1 and the encapsulation layer EPAS, and can be bonded while contacting the second substrate SUB2. In the second area BA2 of the bezel area BZ, the dam member TDM can be bonded while contacting side surfaces of the filling layer FI and the overcoat layer OC2.

A first prevention dam DM1 can be disposed inside the dam member TDM, and a second prevention dam DM2 can be additionally disposed outside the dam member TDM. The first prevention dam DM1 can prevent an organic material of the light emitting layer EL from overflowing to an outer portion. The second prevention dam DM2 can prevent the dam member TDM from overflowing to an outer portion. The dam member TDM and the first and second prevention dams DM1 and DM2 can be disposed in the bezel area BZ in a closed-loop shape surrounding an outer portion of the display area DA.

The first and second prevention dams DM1 and DM2 can each have a structure in which a plurality of insulating layers are stacked. For example, the first and second prevention dams DM1 and DM2 can have a structure in which the overcoat layer OC1 and the bank insulating layer BK are stacked. In each of the first and second prevention dams DM1 and DM2, the bank insulating layer BK can have a structure including a plurality of slits, and overflow or moisture permeation can be minimized or prevented because an overflow path or a moisture permeation path is lengthened by the plurality of slit structures.

Black matrices BM overlapping the first and second prevention dams DM1 and DM2, respectively, can be additionally disposed on the second substrate SUB2.

Referring to FIG. 14A, the circuit element layer TFTL disposed on the first substrate SUB1 can include the pixel circuit PC (in FIG. 3) of each subpixel disposed in the non-transmissive area NTA of each pixel PX in the display area DA, and can include a gate driving circuit GIP disposed in the bezel area BZ. The circuit element layer TFTL can have transmissive areas TA of the respective pixels PX and the respective dummy pixels DPX. The gate driving circuit GIP can be disposed to overlap the dummy pixels DPX disposed in the first area BA1 of the bezel area BZ and the first prevention dam DM1 and the dam member TDM disposed in the second area BA2 of the bezel area BZ, and can have transmissive areas to implement the transparent bezel area BZ.

The overcoat layer OC1 on the circuit element layer TFTL, and the cathode electrode CE among the light emitting element layer EDL on the overcoat layer OC1, can be disposed in the display area DA and can extend to the second area BA2 overlapping the dam member TDM in the bezel area BZ. The light emitting layer EL of the light emitting element layer EDL can be disposed in the display area DA and can extend to the first area BA1 in which the dummy pixels DPX are disposed in the bezel area BZ.

In the light emitting element layer EDL, the light emitting element ED and the bank insulating layer BK can be disposed in the non-transmissive area NTA of each pixel PX in the display area DA, and can be disposed in the non-transmissive area NTA of each dummy pixel DPX in the first area BA1 of the bezel area BZ.

The encapsulation layer EPAS on the light emitting element layer EDL can have a large area covering the circuit element layer TFTL, the overcoat layer OC1, and the light emitting element layer EDL stacked on the first substrate SUB1, and can have a structure of sealing and encapsulating the circuit element layer TFTL, the overcoat layer OC1, and the light emitting element layer EDL.

On the second substrate SUB2, the color filter layer CFL can be disposed in the non-transmissive area NTA of each pixel PX in the display area DA, and can be disposed in the non-transmissive area NTA of each dummy pixel DPX in the first area BA1 of the bezel area BZ. The color filter layer CFL can include color filters CF overlapping emission areas of the light emitting elements ED in the non-transmissive areas NTA of the pixels PX and the dummy pixels DPX, dummy color patterns DCF partially disposed in the transmissive areas TA, and can further include a black matrix BM overlapping non-emission areas of the light emitting elements ED in the non-transmissive areas NTA.

The filling layer FI and the overcoat layer OC2 of the second substrate SUB2 can be disposed in the display area DA and can extend to a part of the second area BA2 of the bezel area BZ to contact an inner surface of the dam member TDM.

Referring to FIG. 14B, a dummy color pattern DCF can be disposed in the transmissive area TA of each pixel PX in the display area DA and in the transmissive area TA of each dummy pixel DPX in the first area BA1 of the bezel area BZ. The dummy color pattern DCF disposed in the transmissive area TA of the dummy pixel DPX can have a form in which an area of the dummy color pattern DCF decreases as the thickness of the light emitting layer EL or the light emitting element layer EDL decreases, in proportion to the thickness of the light emitting layer EL. Since the thickness of the light emitting layer EL or the light emitting element layer EDL decreases as a distance from the display area DA increases, the area of the dummy color pattern DCF can also decrease as a distance from the display area DA increases.

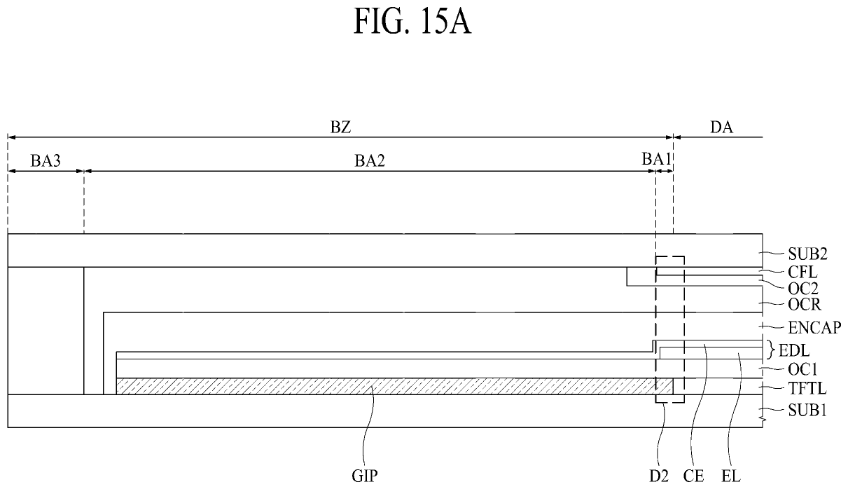

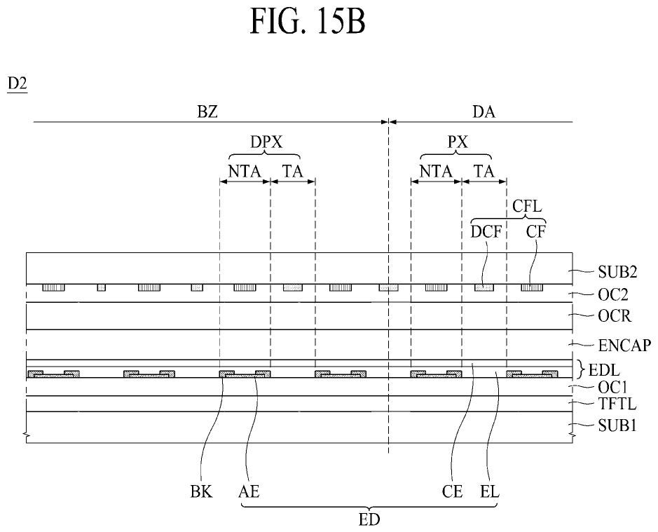

FIG. 15A is a cross-sectional view illustrating a structure of a part of a display area and a bezel area in a transparent display apparatus according to an embodiment of the present disclosure, and FIG. 15B is an enlarged view of portion D2 shown in FIG. 15A.

The transparent display apparatus according to the embodiment shown in FIGS. 15A and 15B is different from that shown in FIGS. 14A and 14B in that the first and second substrates SUB1, SUB2 are bonded together using an optical clear resin OCR instead of the dam member TDM and the filling layer FI shown in FIGS. 14A and 14B, and the other configurations are all the same, so descriptions of the same configurations will be omitted or briefly mentioned.

Referring to FIGS. 15A and 15B, in the transparent display apparatus according to an embodiment, a first substrate SUB1 on which a circuit element layer TFTL, an overcoat layer OC1, a light emitting element layer EDL, and an encapsulation layer EPAS are sequentially stacked and a second substrate SUB2 on which a color filter layer CFL and an overcoat layer OC2 are stacked can be bonded together by an optical clear resin OCR.

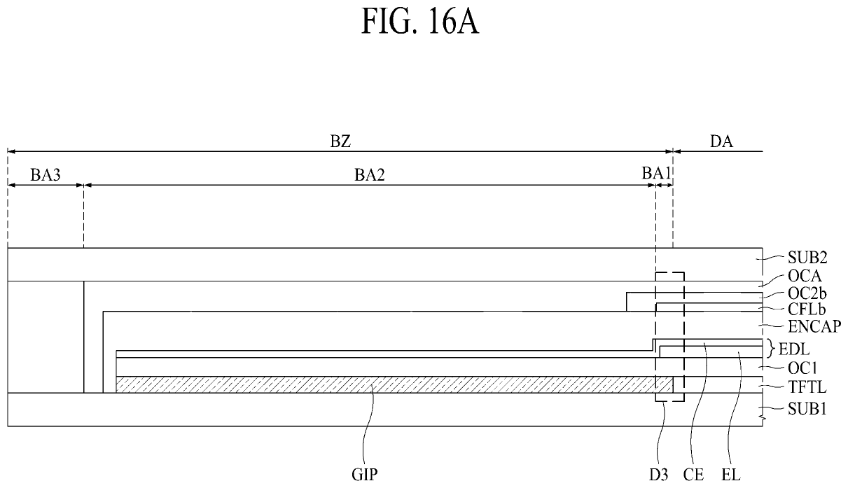

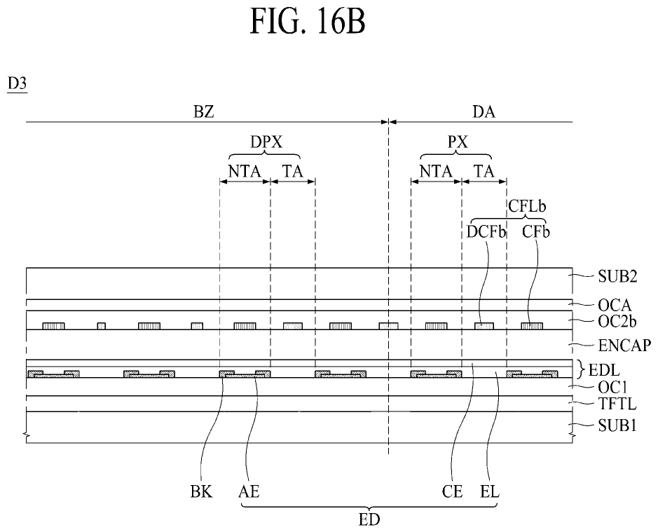

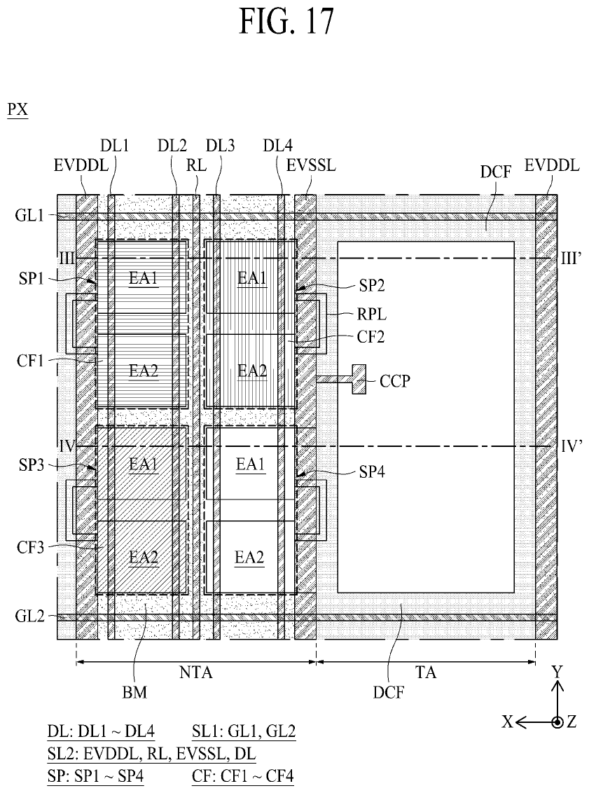

FIG. 16A is a cross-sectional view illustrating a structure of a part of a display area and a bezel area in a transparent display apparatus according to an embodiment of the present disclosure, and FIG. 16B is an enlarged view of portion D3 shown in FIG. 16A.

The transparent display apparatus according to the embodiment shown in FIGS. 16A and 16B differs from that shown in FIGS. 14A and 14B in that a color filter layer CFLb and an overcoat layer OC2b are formed on an encapsulation layer ENCAP on the first substrate SUB1 and are bonded to the second substrate SUB2 through an optical adhesive film OCA, and the other configurations are all the same, so descriptions of the same configurations will be omitted or briefly mentioned.

Referring to FIGS. 16A and 16B, the circuit element layer TFTL, the overcoat layer OC1, the light emitting element layer EDL, and the encapsulation layer ENCAP can be sequentially stacked on the first substrate SUB1.

The encapsulation layer ENCAP can have a stacked structure of first and second inorganic encapsulation layers and an organic encapsulation layer disposed between the first and second inorganic encapsulation layers. The inorganic encapsulation layers can prevent penetration of moisture or oxygen from the outside, and the organic encapsulation layer can serve to cover particles and buffer stress between the respective layers when the display panel is bent.

On the encapsulation layer ENCAP, a color filter layer CFLb including color filters CFb and dummy color filters DCFb can be disposed, and an overcoat layer OC2b covering the color filter layer CFLb can be disposed. The color filter layer CFLb can further include a black matrix.

An optical adhesive film OCA can be disposed on the overcoat layer OC2b, and the second substrate SUB2 can be disposed on the optical adhesive film OCA such that the first and second substrates SUB1 and SUB2 are bonded together through the optical adhesive film OCA. The optical adhesive film OCA can be bonded while contacting the overcoat layer OC2b and the encapsulation layer ENCAP on the first substrate SUB1, and can be bonded while contacting the second substrate SUB2.

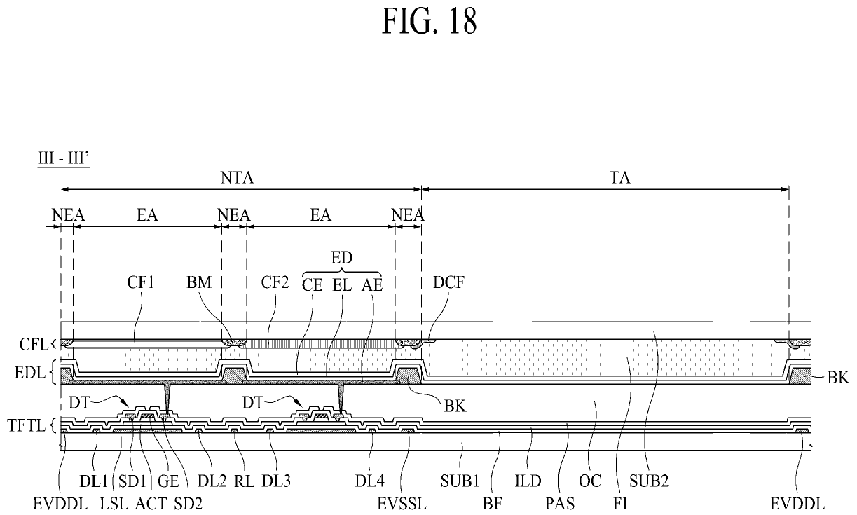

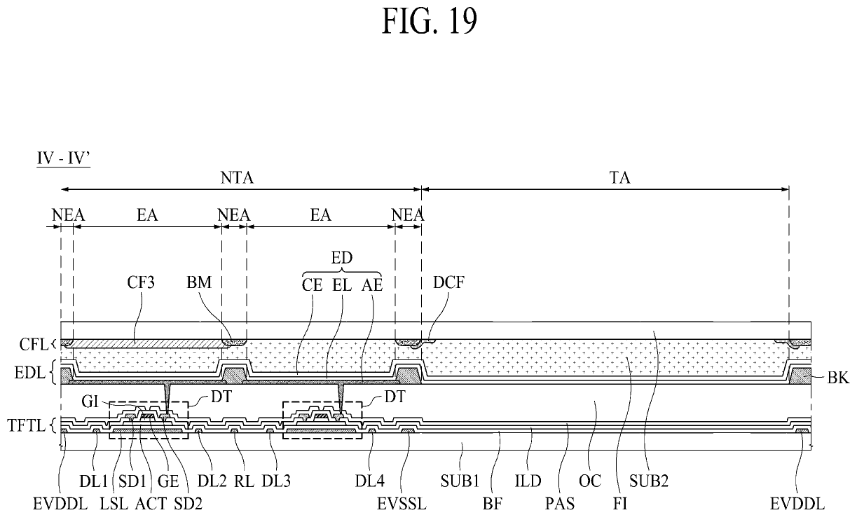

FIG. 17 is a plan view illustrating a pixel configuration of a transparent display apparatus according to an embodiment of the present disclosure, FIG. 18 is a cross-sectional view taken along line III-III′ of FIG. 17, and FIG. 19 is a cross-sectional view taken along line IV-IV′ of FIG. 17.

Referring to FIGS. 17 to 19, each pixel PX according to an embodiment of the present disclosure can include a non-transmissive area NTA in which first to fourth subpixels SP1, SP2, SP3, and SP4 are arranged in a quad type, a transmissive area TA directly adjacent to the non-transmissive area NTA in the second direction X, and a dummy color pattern DCF disposed in a partial area of the transmissive area TA.

The non-transmissive area NTA of the pixel PX can include signal lines SL2 including a high-level power line EVDDL, data lines DL1 to DL4, a reference line RL, and a low-level power line EVSSL, which extend in the first direction Y and are disposed side by side in the second direction X, and signal lines SL1 including gate lines GL1 and GL2 extending in the second direction X. Most of the signal lines SL1 and SL2 can be disposed in a non-emission area NEA in the non-transmissive area NTA, and some signal lines DL can overlap an emission area EA under the light emitting element ED of the subpixel SP. The high level power line EVDDL, the reference line RL, the low level power line EVSSL, and the gate line GL1 can be shared by the first to fourth subpixels SP1 to SP4. The first to fourth data lines DL1 to DL4 can be respectively connected to the first to fourth subpixels SP1 to SP4.

Each of the first to fourth subpixels SP1, SP2, SP3, and SP4 can include at least one light emitting element ED having at least one emission area EA. The first to fourth subpixels SP1, SP2, SP3, and SP4 can correspond to red, green, blue, and white subpixels. For example, the light emitting elements ED of the first to fourth subpixels SP1, SP2, SP3, and SP4 can commonly emit white light. The first subpixel SP1 can include a first color filter CF1 that transmits blue light, the second subpixel SP2 can include a second color filter CF2 that transmits red light, the third subpixel SP3 can include a third color filter CF3 that transmits green light, and the fourth subpixel SP4 can be a white subpixel without a color filter, but is not limited thereto.

Each of the first to fourth subpixels SP1, SP2, SP3, and SP4 can include two light emitting elements ED having two emission areas EA1 and EA2. In each subpixel SP, the two light emitting elements ED can have anodes AE connected through a connection line RPL and can be simultaneously driven by the driving transistor DT. Meanwhile, when a dark spot defect occurs in either one of the two emission areas EA1 and EA2 in each subpixel SP, the connection line RPL can be opened and only the remaining one can be driven, thereby preventing all of the light emitting elements ED of the corresponding subpixel SP from failing to emit light.

The connection line RPL can be disposed to overlap the non-transmissive area NTA and a part of the transmissive area TA. The connection line RPL can be disposed to overlap the dummy color pattern DCF in the transmissive area TA.

In an embodiment of the present disclosure, a cathode contact portion CCP can be disposed in the transmissive area TA of each pixel PX. In order to prevent moisture permeation to the light emitting element ED through the cathode contact portion CCP, the cathode contact portion CCP can be disposed close to a central portion of the transmissive area TA.

Referring to FIGS. 18 and 19, the transparent display apparatus according to an embodiment of the present disclosure can include a circuit element layer TFTL, an overcoat layer OC1, a light emitting element layer EDL, an encapsulation layer EPAS, a filling layer FI, an overcoat layer OC2, and a color filter layer CFL, which are stacked between a first substrate SUB1 and a second substrate SUB2.

The circuit element layer TFTL on the first substrate SUB1 can include a pixel circuit including signal lines SL1 and SL2 and the driving transistor DT.

A first metal layer (light shielding metal layer) including a light shielding electrode LS, power lines EVDDL and EVSSL, a reference line RL, and data lines DL1 to DL4 can be disposed on the first substrate SUB1.

A buffer layer BF can be disposed on the first substrate SUB1 on which the first metal layer is formed, and an active layer ACT can be disposed on the buffer layer BF. The buffer layer BF can prevent impurities such as hydrogen from entering the active layer ACT through the substrate SUB1.

The driving transistor DT can include the active layer ACT, a gate insulating layer GI, a gate electrode GE, first and second source-drain electrodes SD1 and SD2, and can further include the light shielding electrode LS. The light shielding electrode LS can be connected to either one of the first and second source-drain electrodes SD1 and SD2.

The active layer ACT can include a channel region and first and second conductive regions facing each other in a channel length direction with the channel region interposed therebetween. The active layer ACT can include any one of an amorphous silicon semiconductor material, a polysilicon semiconductor material, and a metal oxide semiconductor material. For example, the semiconductor layer ACT can include at least one of IGZO (InGaZnO) based, IGO (InGaO) based, IGZTO (InGaZnSnO) based, GZTO (GaZnSnO) based, GZO (GaZnO) based, GO (GaO) based, TO (SnO) based, ITO (InSnO) based, ITZO (InSnZnO) based, IZO (InZnO) based, ZO (ZnO) based, IO (InO) based, InO (InO) based, ZnO based, and FIZO (FeInZnO) based metal oxide semiconductor materials. The active layer ACT can have a single layer structure or a multi-layer structure in which at least two oxide semiconductor layers are stacked.

The gate electrode GE can overlap the channel region of the semiconductor layer ACT with the gate insulating layer GI interposed therebetween. The gate electrode GE can be formed as a second metal layer (gate metal layer) on the gate insulating layer GI together with the gate line GL.

An interlayer insulating layer ILD covering the active layer ACT, the gate electrode GE, and the gate insulating layer GI can be disposed on the buffer layer BF. A third metal layer (source-drain metal layer) including first and second source-drain electrodes SD1 and SD2 can be disposed on the interlayer insulating layer ILD. The first and second source-drain electrodes SD1, SD2 can be connected to the first and second conductive regions of the active layer ACT, respectively, through respective contact holes passing through the interlayer insulating layer ILD.

Each of the first, second, and third metal layers can have a single layer structure including at least one of aluminum (Al), molybdenum (Mo), chromium (Cr), tantalum (Ta), neodymium (Nd), titanium (Ti), copper (Cu), gold (Δu), silver (Ag), and alloys thereof, or can have a multi-layer structure in which at least two metal layers are stacked.

A passivation layer PAS covering the first and second source-drain electrodes SD1 and SD2 can be formed on the interlayer insulating layer ILD, and an overcoat layer OC can be formed on the passivation layer PAS.

The buffer layer BF, the gate insulating layer GI, the interlayer insulating layer ILD, and the passivation layer PAS can be referred to as a plurality of inorganic insulating layers. Each of the plurality of inorganic insulating layers can have a single layer or multi-layer structure including an insulating material. The buffer layer BF and the gate insulating layer GI can include an oxide-based insulating material such as silicon oxide (SiOx) or aluminum oxide (Al₂O₃) having a low hydrogen content. The interlayer insulating layer ILD and the passivation layer PAS can have a single layer or multi-layer structure including at least one of silicon oxide (SiOx) and silicon nitride (SiNx).

The light emitting element layer EDL on the overcoat layer OC1 can include a plurality of light emitting elements ED disposed in the non-transmissive area NTA of the pixel PX. In the non-transmissive area NTA, the light emitting elements ED can be disposed to overlap the pixel circuit of each subpixel SP of the circuit element layer TFTL and can be connected to the driving transistor DT.

The light emitting element ED can include an anode electrode AE disposed on the overcoat layer OC, a bank insulating layer BK covering an edge of the anode electrode AE and defining an emission area EA, a light emitting layer EL on the anode electrode AE and the bank insulating layer BK, and a cathode electrode CE on the light emitting layer EL. The anode electrode AE and the bank insulating layer BK can be disposed only in the non-transmissive area NTA of the pixel PX, whereas the light emitting layer EL and the cathode electrode CE can be commonly disposed over the non-transmissive area NTA and the transmissive area TA of the pixel PX. The anode electrode AE can be connected to the driving transistor DT through a contact hole passing through the overcoat layer OC and the passivation layer PAS.

An encapsulation layer EPAS sealing the light emitting element layer EDL can be disposed on the light emitting element layer EDL to prevent moisture or oxygen from penetrating into the light emitting element ED.

On an inner surface of the second substrate SUB2 facing the first substrate SUB1, a color filter layer CFL including color filters CF1 to CF3 and a dummy color filter DCF can be disposed. The color filter layer CFL can further include a black matrix BM. The color filters CF1 to CF3 can be disposed to overlap emission areas EA of the respective light emitting elements ED in the non-transmissive area NTA, and the black matrix BM can be disposed to overlap non-emission areas NEA. The dummy color filter DCF can be partially disposed to overlap the transmissive area TA in various forms. A part of the dummy color filter DCF can overlap the black matrix BM. An overcoat layer can be further disposed on the color filter layer CFL.

A filling layer FI can be formed between the encapsulation layer EPAS and the color filter layer CFL.

The structures of the light emitting element layer EDL and the color filter layer CFL of the pixel PX can be equally applied to the dummy pixels in the bezel area, and the circuit element layer TFTL of the dummy pixels can include gate driving circuits. As described above, in the bezel area, the area of the dummy color pattern can have a form in which the area thereof decreases as the thickness of the light emitting layer EL decreases, in proportion to the thickness of the light emitting layer EL or the light emitting element layer EDL.

As described above, the transparent display apparatus according to an embodiment of the present disclosure can reduce or minimize a color difference between a display area and a bezel area depending on the presence or absence of a light emitting layer by disposing a dummy color pattern (color compensation pattern) in a partial area of a transmissive area to compensate for a color change in the transmissive area caused by the light emitting layer.

The transparent display apparatus according to an embodiment of the present disclosure can reduce or minimize a color difference in the bezel area according to a thickness of the light emitting layer by configuring the area of a dummy color pattern (color compensation pattern) disposed in a partial area of a transmissive area of a dummy pixel in the bezel area to gradually vary according to the thickness of the light emitting layer (light emitting element, light emitting element layer).

The transparent display apparatus according to an embodiment of the present disclosure can improve clarity of an on-screen image and thus improve display quality by reducing or minimizing a color change in the transmissive area using a dummy color pattern (color compensation pattern), such as a blue color filter, without an additional mask process.

The transparent display apparatus according to an embodiment of the present disclosure can improve display quality by using a dummy color pattern (color compensation pattern) disposed in transmissive areas of a display area and a bezel area, and can thus achieve a low-power effect because it can have the same luminous efficiency at lower power or can improve luminous efficiency even more, as compared with a transparent display apparatus without the dummy color pattern (color compensation pattern).

The transparent display apparatus according to the present disclosure can be applied to various electronic devices. For example, the transparent display apparatus according to the present disclosure can be applied to, but is not limited to, a mobile device, a video phone, a smart watch, a watch phone, a wearable device, a foldable device, a rollable device, a bendable device, a flexible device, a curved device, a navigation device, an in-vehicle navigation device, an in-vehicle display apparatus, a television, a wallpaper display apparatus, signage equipment, a robot, home appliances, a transportation means, etc.

The features, structures, effects, and the like described in the various examples of the present disclosure described above are included in at least one example of the present disclosure and are not necessarily limited to only one example. Furthermore, the features, structures, effects, and the like exemplified in at least one example of the present disclosure can be combined or modified for other examples by those skilled in the art to which the technical spirit of the present disclosure pertains. Accordingly, contents related to such combinations and modifications should be construed as being included in the technical scope or the scope of rights of the present disclosure.

The present disclosure described above is not limited to the above-described embodiments and the accompanying drawings, and it will be apparent to those skilled in the art to which the present disclosure pertains that various substitutions, modifications, and changes can be made without departing from the technical spirit of the present disclosure. Therefore, the scope of the present disclosure is defined by the claims described below, and all changes or modified forms derived from the meaning, scope, and equivalents of the claims should be construed as being included in the scope of the present disclosure.

What is claimed is:

1. A transparent display apparatus comprising:
a display area in which a plurality of pixels are disposed, each of the plurality of pixels having a first non-transmissive area and a first transmissive area;
a bezel area adjacent to the display area and in which a plurality of dummy pixels are disposed, each of the plurality of dummy pixels having a second non-transmissive area and a second transmissive area;
a first dummy color pattern partially disposed in a first transmissive area among the first transmissive areas; and
a second dummy color pattern partially disposed in a second transmissive area among the second transmissive areas,
wherein an area of the second dummy color pattern varies depending on a position in the bezel area.

2. The transparent display apparatus of claim 1,
wherein the area of the second dummy color pattern varies according to a thickness of a light emitting layer disposed in the plurality of dummy pixels.

3. The transparent display apparatus of claim 2,
wherein the thickness of the light emitting layer disposed in the plurality of dummy pixels gradually decreases as a distance from the display area increases, relative to a thickness of a light emitting layer disposed in the plurality of pixels.

4. The transparent display apparatus of claim 3,
wherein an area of the second dummy color pattern disposed in the second transmissive area of the plurality of dummy pixels gradually decreases, as the thickness of the light emitting layer decreases, relative to an area of the first dummy color pattern disposed in the first transmissive area.

5. The transparent display apparatus of claim 2,
wherein an amount of change in the area of the second dummy color pattern in the plurality of dummy pixels is determined in consideration of an area of the first dummy color pattern disposed in the first transmissive area and a number of dummy pixels in a direction in which a thickness of the light emitting layer decreases in the bezel area.

6. The transparent display apparatus of claim 5,
wherein the amount of change in the area of the second dummy color pattern in the plurality of dummy pixels is determined by dividing an area ratio occupied by the first dummy color pattern in the first transmissive area by a value of the number (N)+1 of dummy pixels in a direction in which the thickness of the light emitting layer decreases.

7. The transparent display apparatus of claim 1,
wherein each of the first dummy color pattern and the second dummy color pattern is a dummy blue pattern configured to transmit blue light.

8. The transparent display apparatus of claim 1,
wherein each of the fist dummy color pattern and the second dummy color pattern is disposed at a central portion of the respective first or second transmissive area or is disposed in a shape surrounding an edge of the respective first or second transmissive area.

9. The transparent display apparatus of claim 1, further comprising:
color filters disposed in subpixels of the plurality of pixels, excluding a white subpixel among first to fourth subpixels respectively provided in each of the first non-transmissive area and the second non-transmissive area.

10. The transparent display apparatus of claim 9,
wherein each of the fist dummy color pattern and the second dummy color pattern is disposed on a same layer as the color filters or is disposed on a circuit element layer including pixel circuits of the plurality of pixels.

11. The transparent display apparatus of claim 1,
wherein the plurality of dummy pixels overlap a gate driving circuit disposed in the bezel area.

12. The transparent display apparatus of claim 1,
wherein an area occupied by the first dummy color pattern in the first transmissive area is 5% to 25%, relative to an area of the first transmissive area.

13. A transparent display apparatus comprising:
a display area in which pixels are disposed, each of the pixels having a transmissive area and a non-transmissive area;
a bezel area adjacent to the display area and in which dummy pixels are disposed, each of the dummy pixels having a transmissive area and a non-transmissive area; and
a dummy color pattern partially disposed in the transmissive area of a pixel among the pixels and in the transmissive area of a dummy pixel among the dummy pixels,
wherein, in the bezel area, an area of the dummy color pattern of the dummy pixel varies according to a distance from the display area.

14. The transparent display apparatus of claim 13,
wherein, in the bezel area, the area of the dummy color pattern of the dummy pixel gradually decreases, as a distance from the display area increases, relative to an area of the dummy color pattern of the pixel.

15. The transparent display apparatus of claim 13, further comprising:
color filters disposed in subpixels of the pixels, other than a white subpixel among first to fourth subpixels respectively provided in the non-transmissive area of the pixel and the non-transmissive area of the dummy pixel.

16. The transparent display apparatus of claim 15, further comprising:
a circuit element layer disposed on a first substrate and including a pixel circuit of each of the subpixels provided in the non-transmissive area of the pixel;
a light emitting element layer disposed on the circuit element layer;
an encapsulation layer covering the light emitting element layer;
a color filter layer disposed on the encapsulation layer and including the color filters and the dummy color pattern; and
a second substrate disposed on the color filter layer.

17. The transparent display apparatus of claim 15, further comprising:
a circuit element layer disposed on a first substrate, and including a pixel circuit of each of subpixels provided in the non-transmissive area of the pixel,
wherein the dummy color pattern is disposed on the circuit element layer;
an overcoat layer covering the dummy color pattern on the circuit element layer;
a light emitting element layer disposed on the overcoat layer;
an encapsulation layer covering the light emitting element layer;
a color filter layer disposed on the encapsulation layer and including the color filters; and
a second substrate disposed on the color filter layer.

18. The transparent display apparatus of claim 16,
wherein the circuit element layer further includes a gate driving circuit overlapping the non-transmissive area of the dummy pixels in the bezel area.

19. The transparent display apparatus of claim 15, further comprising:
a light emitting element layer including an anode electrode, a bank insulating layer covering an edge of the anode electrode, a light emitting layer, and a cathode electrode,
wherein the anode electrode and the bank insulating layer are disposed in the non-transmissive area of the pixel and the non-transmissive area of the dummy pixel, and
wherein the light emitting layer and the cathode electrode are commonly disposed in the transmissive area and the non-transmissive area of the pixel and in the transmissive area and the non-transmissive area of the dummy pixel.

20. The transparent display apparatus of claim 15,
wherein each of red, green, blue, and white subpixels respectively provided in the non-transmissive area of the pixel and in the non-transmissive area of the dummy pixel includes:
a pixel circuit,
a light emitting element overlapping the pixel circuit, and configured to be driven by the pixel circuit, and
red, green, and blue color filters overlapping the light emitting elements of the red, green, and blue subpixels, respectively,
wherein the light emitting elements of the red, green, blue, and white subpixels are configured to emit white light.
